(19) United States
(12) Patent Application Publication
(10) Pub. No.: US 2013/0113005 A1
(43) Pub. Date: May 9, 2013

(54) SEMICONDUCTOR LIGHT EMITTING DEVICE AND FABRICATION METHOD THEREOF

(71) Applicant: Samsung Electronics Co., Ltd., Gyeonggi-do (KR)

(72) Inventors: Wan Ho LEE, Gyeonggi-do (KR); Seung Woo CHOI, Seoul (KR); Sang Yeob SONG, Gyeonggi-do (KR); Jong Rak SOHN, Gyeonggi-do (KR)

(73) Assignee: SAMSUNG ELECTRONICS CO., LTD., Gyeonggi-do (KR)

(21) Appl. No.: 13/669,179

(22) Filed: Nov. 5, 2012

(30) Foreign Application Priority Data
Nov. 4, 2011 (KR) 10-2011-0114665

(51) Int. Cl. H01L 33/10

(52) U.S. Cl. 257/98; 257/E33.068

(57) ABSTRACT

A semiconductor light emitting device and a fabrication method thereof are provided. The semiconductor light emitting device includes a light emitting structure including a first conductivity-type semiconductor layer, an active layer, and a second conductivity-type semiconductor layer. A reflective structure is formed on the light emitting structure and includes a nano-rod layer comprised of a plurality of nano-rods and air filling space between the plurality of nano-rods and a reflective metal layer formed on the nano-rod layer.

### CROSS-REFERENCE TO RELATED APPLICATIONS

The present application claims the priority of Korean Patent Application No. 10-2011-0114665 filed on Nov. 4, 2011, in the Korean Intellectual Property Office, the disclosure of which is incorporated herein by reference.

### TECHNICAL FIELD

The present disclosure relates to a semiconductor light emitting device and a fabrication method thereof.

### BACKGROUND

In general, nitride semiconductors have been widely used in green or blue light emitting diodes (LED) or in laser diodes provided as a light source in a full-color display, an image scanner, various signaling systems, or an optical communication device. A nitride semiconductor light emitting device may be provided as a light emitting device having an active layer emitting light of various colors, including blue and green, through the recombination of electrons and holes.

As remarkable progress has been made in the area of nitride semiconductor light emitting devices since they were first developed, the utilization thereof has been greatly expanded and research into utilizing semiconductor light emitting devices for the purpose of general illumination devices, as well as for light sources in electronic devices, has been actively undertaken. In particular, conventional nitride light emitting devices have largely been used as components in low-current/low output mobile products, and recently, the utilization of nitride light emitting devices has extended into the field of high current/high output devices. Thus, research into improving the luminous efficiency and quality of semiconductor light emitting devices is actively ongoing.

In order to improve luminous efficiency of semiconductor light emitting devices, light emitted from semiconductor light emitting devices may be guided in a desired direction to enhance light extraction efficiency, and to this end, a metal reflective layer may be formed within or on a surface of a chip. However, the application of a metal thin film as a reflective layer is vulnerable to heat, and as a result, the adhesiveness thereof, with regard to a semiconductor layer, may be degraded.

### SUMMARY

An aspect of the present disclosure provides a semiconductor light emitting device having improved light extraction efficiency, and a fabrication method thereof.

Another aspect of the present disclosure provides a semiconductor light emitting device having improved thermal reliability in a reflective layer, and a fabrication method thereof.

According to yet another aspect of the present disclosure, there is provided a semiconductor light emitting device including: a light emitting structure including a first conductivity-type semiconductor layer, an active layer, and a second conductivity-type semiconductor layer A reflective structure is formed on the light emitting structure and includes a nano-rod layer comprised of a plurality of nano-rods and air filling space arranged between the plurality of nano-rods and a reflective metal layer formed on the nano-rod layer.

The space in which the plurality of nano-rods are formed may have different refractive indices than the space filled with air arranged between the nano-rods, with respect to a wavelength of light emitted from the active layer.

The reflective structure may be formed such that the nano-rod layer thereof is in direct contact with the second conductivity-type semiconductor layer of the light emitting structure.

The plurality of nano-rods may be comprised of a material having electrical conductivity and light transmissivity.

The material having electrical conductivity and light transmissivity may be one of a transparent conductive oxide and a transparent conductive nitride.

The transparent conductive oxide may be at least one of ITO, CIO, and ZnO.

The thickness of the nano-rod layer may be defined by an integer multiple of λ/(4n), wherein n is a refractive index of the nano-rods and λ is a wavelength of light emitted from the active layer.

The semiconductor light emitting device may further include a conductive substrate formed on the reflective structure.

The semiconductor light emitting device may further include a substrate for growth of a semiconductor having one surface on which the light emitting structure is formed.

The reflective structure may be formed on a surface of the substrate for growth of a semiconductor opposite the surface on which the light emitting structure is formed.

The reflective structure may be formed on the second conductivity-type semiconductor layer of the light emitting structure formed on the substrate for growth of a semiconductor.

According to another aspect of the present disclosure, there is provided a method for fabricating a semiconductor light emitting device. The method includes preparing a light emitting structure including a first conductivity-type semiconductor layer, an active layer, and a second conductivity-type semiconductor layer; forming a nano-rod layer comprised of a plurality of nano-rods spaced apart on the light emitting structure; and forming a reflective metal layer on the nano-rod layer such that space between the plurality of nano-rods is filled with air.

The thickness of the nano-rod layer may be defined by an integer multiple of λ/(4n), wherein n is a refractive index of the nano-rods and λ is a wavelength of light emitted from the active layer.

The reflective metal layer may be formed through sputtering or e-beam evaporation.

The nano-rods may be directly grown from the second conductivity-type semiconductor layer.

The method may further include forming a conductive substrate on the reflective metal layer.

The method may further include sequentially forming the first conductivity-type semiconductor layer, the active layer, and the second conductivity-type semiconductor layer of the light emitting structure on a substrate for growth of a semiconductor.

The nano-rod layer may be formed on a surface of the substrate for growth of a semiconductor opposite a surface of the substrate for growth of a semiconductor on which the light emitting structure is formed.

According to another aspect of the present disclosure, there is provided a light emitting device package comprising a semiconductor light emitting device comprising a light emitting structure including a first conductivity-type semiconductor layer, an active layer, and a second conductivity-type semiconductor layer, and a reflective structure formed on the light emitting structure and including a nano-rod layer comprised of a plurality of nano-rods and air filling space between the plurality of nano-rods and a reflective metal layer formed on the nano-rod layer. The device includes a first electrode; a first terminal unit; and a second terminal unit. The semiconductor light emitting device is electrically connected to the first and second terminal units.

The light emitting device package may further comprises a lens unit formed above the semiconductor light emitting device.

The lens unit may encapsulate the semiconductor light emitting device.

The lens unit may fix the semiconductor light emitting device 100 and the first and second terminal units.

The lens unit may be made of a resin. In some examples, the resin may comprise any one of epoxy resin, silicon resin, strained silicon resin, a urethane resin, an oxetane resin, acryl resin, polycarbonate resin, and polyimide resin.

Depressions and protrusions may be formed on an upper surface of the lens unit.

The lens unit may include wavelength conversion phosphor particles for converting a wavelength of light emitted from the active layer of the semiconductor light emitting device. In some examples, the phosphor may be one or more from the group consisting of yellow phosphor, red phosphor, and green phosphor. In other examples, the phosphor may be at least one from the group consisting of YAG-based phosphor material, a TAG-based phosphor material, a silicate-based phosphor material, a sulfide-based phosphor material, and a nitride-based phosphor material.

The lens unit may have a hemispherical shape.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view schematically showing a semiconductor light emitting device according to a first example of the present disclosure;

FIG. 2 is an enlarged cross-sectional view showing a portion of the semiconductor light emitting device illustrated in FIG. 1;

FIG. 3 is a perspective view schematically showing a semiconductor light emitting device according to a second example of the present disclosure;

FIG. 4 is a perspective view schematically showing a semiconductor light emitting device according to a third example of the present disclosure;

FIGS. 5A through 5E are schematic sectional views showing a method for fabricating the semiconductor light emitting device according to the first example of the present disclosure; and

FIGS. 6A through 6C are schematic sectional views showing a mounting configuration of a semiconductor light emitting device package according to the first to third examples of the present disclosure.

### DETAILED DESCRIPTION

Examples of the present disclosure will now be described in detail with reference to the accompanying drawings.

The disclosure may, however, be embodied in many different forms and should not be construed as being limited to the examples set forth herein. Rather, these examples are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like components.

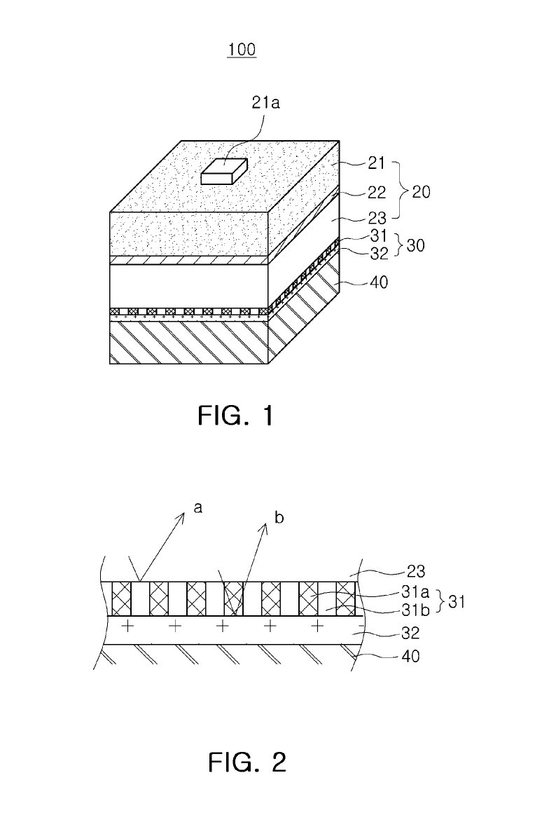

FIG. 1 is a perspective view schematically showing a semiconductor light emitting device according to a first example of the present disclosure.

With reference to FIG. 1, a semiconductor light emitting device 100 according to the present example includes a light emitting structure 20 including a first conductivity-type semiconductor layer 21, an active layer 22, and a second conductivity-type semiconductor layer 23, and a reflective structure 30 formed on the light emitting structure 20. The reflective structure 30 may have a nano-rod layer 31 including a plurality of nano-rods and air filling space between the nano-rods, and a reflective metal layer 32 formed on the nano-rod layer 31.

A first electrode 21a may be formed on the first conductivity-type semiconductor layer 21 of the light emitting structure 20 and electrically connected to the first conductivity-type semiconductor layer 21, and a conductive substrate 40 may be formed on the reflective structure 30. Here, the conductive substrate 40 may be electrically connected to the second conductivity-type semiconductor layer 23 so as to serve as a second electrode.

In the present example, the first and second conductivity-type semiconductor layers 21 and 23 may be n-type and p-type semiconductor layers, respectively, and may be made of a nitride semiconductor. Thus, in the present example, the first and second conductivity-types may be understood to indicate n-type and p-type conductivities, respectively, but the present disclosure is not limited thereto. The first and second conductivity-type semiconductor layers 21 and 23 may be made of a material expressed by an empirical formula AₗₓI_{ny}G_{a(1-x-y)}N (here, 0≦x≦1, 0≦y≦1, 0≦x+y≦1), and such a material may include GaN, AlGaN, InGaN, and the like.

The active layer 22 disposed between the first and second conductivity-type semiconductor layers 21 and 23 emits light having a certain level of energy according to electron and hole recombination, and may have a multi-quantum well (MQW) structure in which a quantum well and a quantum barrier are alternately stacked. Here, the MQW structure may be, for example, an InGaN/GaN structure. Meanwhile, the first and second conductivity-type semiconductor layers 21 and 23 and the active layer 22 may be formed by using a conventional semiconductor layer growth process such as such as metal organic chemical vapor deposition (MOCVD), hydride vapor phase epitaxy (HVPE), molecular beam epitaxy (MBE), or the like.

The first electrode 21a may be formed on the first conductivity-type semiconductor layer 21 and electrically connected to the first conductivity-type semiconductor layer, and here, in order to enhance an ohmic-contact function between the first conductivity-type semiconductor layer 21 and the first electrode 21a, a transparent electrode made of ITO, ZnO, or the like, may be further provided therebetween. In the case of the structure illustrated in FIG. 1, the first electrode 21a is formed at the center of an upper surface of the first conductivity-type semiconductor layer 21, but the position and a connection structure of the first electrode 21a may be variably modified as necessary. Although not shown, a branch electrode extending from the first electrode 21a may be further provided to uniformly distribute a current. Here, the first electrode 21a may be a bonding pad.

The conductive substrate 40 formed on the reflective structure 30 may serve as a support supporting the light emitting structure including the first and second conductivity-type semiconductor layers 21 and 23 and the active layer 22 during a process such as a laser lift-off, or the like, for removing a substrate for growth of a semiconductor (not shown) from the first conductivity-type semiconductor layer 21, the active layer 22, and the second conductivity-type semiconductor layer 23 sequentially formed on the growth substrate (not shown). The conductive substrate 40 may be made of a material including any one of Au, Ni, Al, Cu, W, Si, Se, and GaAs, for example, made of a material doped with Al in an Si substrate.

In the present example, the conductive substrate 40 may be bonded to the reflective structure by the medium of a conductive adhesive layer (not shown). The conductive adhesive layer may be made of a eutectic metal material such as, for example, AuSn. Also, the conductive substrate 40 may serve as a second electrode applying an electrical signal to the second conductivity-type semiconductor layer 23, and, as shown in FIG. 1, when the electrode is formed in a vertical direction, a current flow region can be enlarged to enhance a current distribution function.

The reflective structure 30 may be formed on the light emitting structure 20 and may include the nano-rod layer 31 including a plurality of nano-rods and air filling a space between the nano-rods, and the reflective metal layer 32 formed on the nano-rod layer 31.

The plurality of nano-rods may be made of a material having electrical conductivity and transparency (or translucency). Specifically, the plurality of nano-rods may be made of a transparent conductive oxide (TCO) or a transparent conductive nitride (TCN). Here, the transparent conductive oxide may be ITO, CIO, ZnO, or the like.

The reflective metal layer 32 may include a material such as Ag, Ni, Al, Rh, Pd, Ir, Ru, Mg, Zn, Pt, Au, or the like, and in FIG. 1, only a single reflective metal layer 32 is illustrated, but alternately, the reflective metal layer 32 may have a structure including two or more layers. In this case, the two or more layers of the structure may be Ni/Ag, Zn/Ag, Ni/Al, Zn/Al, Pd/Ag, Pd/Al, Ir/Ag, Ir/Au, Pt/Ag, Pt/Al, Ni/Ag/Pt, or the like, but the present disclosure is not limited thereto.

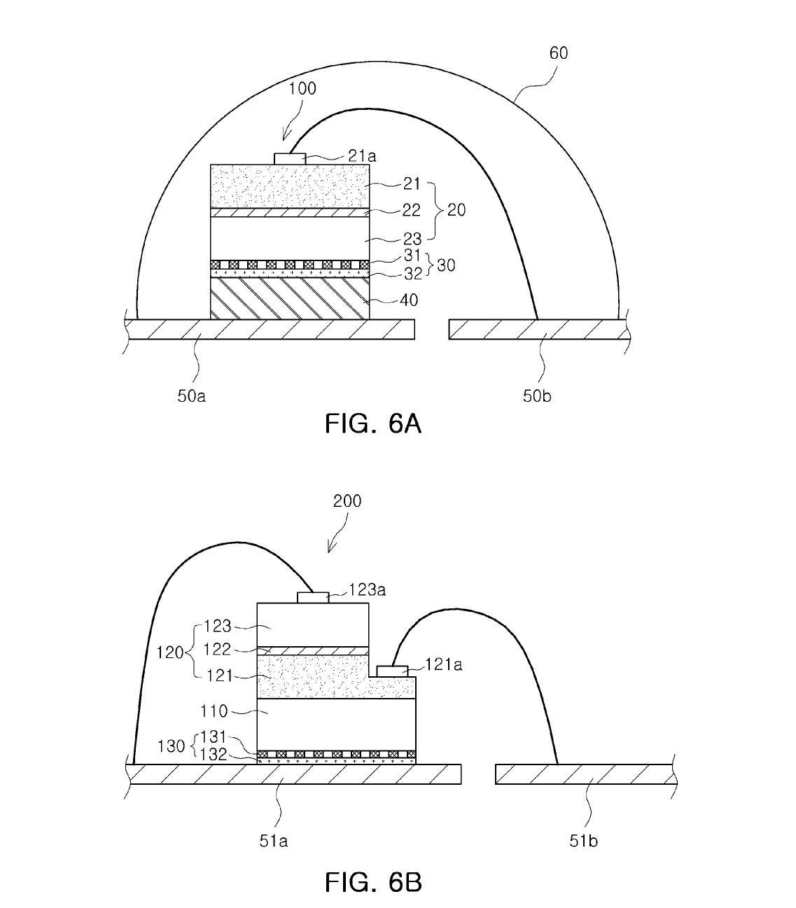

The plurality of nano-rods and the reflective metal layer 32 may be formed through a known deposition process, e.g., metal organic chemical vapor deposition (MOCVD), molecular beam epitaxy (MBE), sputtering, or the like, and details thereof will be described hereinafter with reference to FIG. 5.

In FIG. 1, it is illustrated that the reflective metal layer 32 formed on the nano-rod layer 31 is a completely separate layer from the nano-rod layer 31. However, metal material that was used for forming the reflective metal layer 32 may also be formed in parts of regions 31b between the plurality of nano-rods 31a. Thus, an overlapping region of the reflective metal layer 32 and the nano-rod layer 31 as viewed from the side direction of the light emitting device may exist in the semiconductor device.

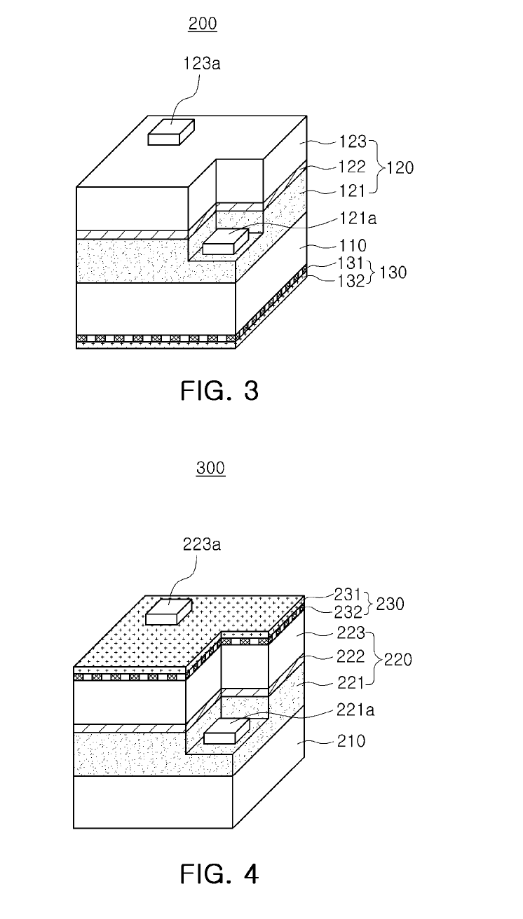

FIG. 2 is an enlarged cross-sectional view showing a portion of the semiconductor light emitting device illustrated in FIG. 1. Specifically, FIG. 2 schematically shows a section of a region adjacent to the reflective structure 30 formation region.

With reference to FIG. 2, the reflective structure 30 formed on the light emitting structure 20 may include the nano-rod layer 31 including the plurality of nano-rods 31a and air filling space 31b between the nano-rods 31a and the reflective metal layer 32 formed on the nano-rod layer 31. Here, the reflective structure 30 may be formed such that the second conductivity-type semiconductor layer 23 of the light emitting structure 20 is in contact with the nano-rod layer 31 of the reflective structure 30. Light generated from the active layer 22 of the light emitting structure 20 and emitted downward may be effectively reflected from the reflective structure 30 and led upwardly.

In the case of the semiconductor light emitting device 100 according to the present example, a main light emission surface may include an upper surface of the light emitting structure 20, namely, in a direction toward the first conductivity-type semiconductor layer 21, and a lateral surface of the light emitting structure 20. Thus, since light emitted toward the conductive substrate 40 is guided to the upper and lateral surfaces of the light emitting structure 20, light output can be enhanced.

In detail, a light beam (a), which has reached the air layer region between the plurality of nano-rods 31a, in light emitted toward the conductive substrate 40 from the active layer 22 has a small critical angle due to a large difference in refractive indices between the second conductivity-type semiconductor layer 23 and the air 31b between the nano-rods. Namely, since the air 31b has a small refractive index (about 1), a majority of light made incident to exceed the critical angle due to the large difference in the refractive index between the air 31b and the second conductivity-type semiconductor layer 23 is totally reflected from the interface therebetween, thus guiding light upwardly.

Meanwhile, in the present example, the plurality of nano-rods 31a and the reflective metal layer 32 have an omni-directional reflector (ODR) structure having high reflectivity, thus minimizing a phenomenon in which light emitted from the active layer 22 is absorbed to become extinct. In this case, in order to implement the ODR structure, the thickness of the nano-rod layer 31 is an integer multiple of λ/(4n), wherein n is a refractive index of the nano-rods 31a and λ is a wavelength of light emitted from the active layer 22.

Namely, providing that the thickness condition is satisfied, the plurality of nano-rods 31a and the reflective metal layer 32 can have the ODR structure, and reflectivity can be maximized when light emitted from the active layer 22 reaches a portion (b) between the plurality of nano-rods 31a and the reflective metal layer 32. The reflective metal layer 32 is formed on the nano-rod layer 31 (such that it is in contact with the nano-rod layer 31) and may include a material having high extinction coefficient, e.g., Ag, Al, Au, or the like.

In the present example, in the reflective structure 30, the space in which the plurality of nano-rods 31a are formed and the region 31b in which air is formed to fill between the nano-rods 31a may have different refractive indices with respect to a wavelength of light emitted from the active layer 22. In order for portions of the reflective structure 30 to have different refractive indices, the width of the nano-rods 31a, the interval between the plurality of nano-rods 31a, or the like, may be adjusted.

In this case, reflective efficiency of each region is maximized to enhance light extraction efficiency, and since the air layer 31b is formed between the plurality of nano-rods 31a, a degradation of the reflective metal layer due to high heat emitted from the light emitting structure 20 can be prevented. Also, the plurality of nano-rods 31a may serve as a current path for applying an electrical signal to the second conductivity-type semiconductor layer 23 from the conductive substrate 40, and thus, the nano-rods 31a may be made of a material having electrical conductivity.

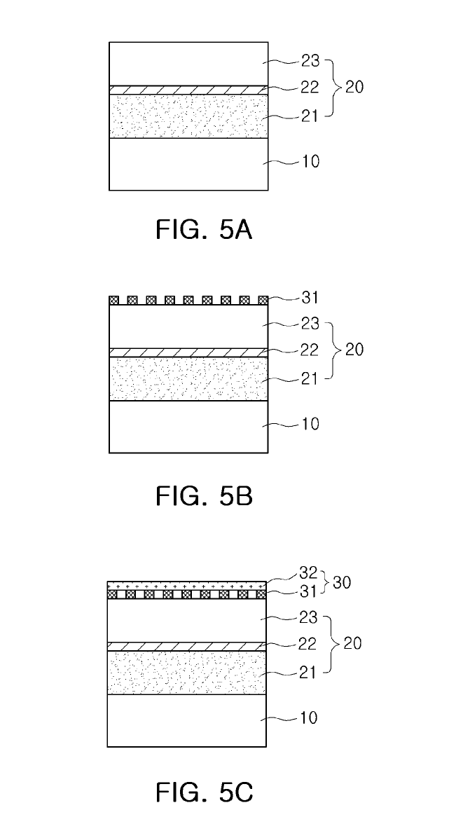

FIG. 3 is a perspective view schematically showing a semiconductor light emitting device according to a second example of the present disclosure.

With reference to FIG. 3, the semiconductor light emitting device 200 may include a substrate for growth of a semiconductor 110, a light emitting structure 120 formed on the substrate for growth of a semiconductor 110, and a reflective structure 130 formed on a surface of the substrate for growth of a semiconductor 110 opposed to the surface of substrate for growth of a semiconductor 110 on which the light emitting structure 120 is formed.

The light emitting structure 120 may include a first conductivity-type semiconductor layer 121, an active layer 122, and a second conductivity-type semiconductor layer 123 sequentially formed on the substrate for growth of a semiconductor 110. First and second electrodes 121a and 123a for applying an electrical signal from the outside may be formed on the first and second conductivity-type semiconductor layers 121 and 123, respectively.

As the substrate for growth of a semiconductor 110, a substrate made of a material such as SiC, MgAl₂O₄, MgO, LiAlO₂, LiGaO₂, GaN, or the like, may be used. In this case, sapphire is a crystal having Hexa-Rhombo R3c symmetry, of which lattice constants in c-axis and a-axis directions are 13.001 Å and 4.758 Å, respectively. The sapphire crystal has a C plane (0001), an A plane (1120), an R plane (1102), and the like. In this case, a nitride thin film can be relatively easily formed on the C plane of the sapphire crystal and because sapphire crystal is stable at high temperatures, sapphire crystal is commonly used as a material for a nitride growth substrate. A buffer layer (not shown) is employed as an undoped semiconductor layer made of a nitride, or the like, to alleviate a lattice defect in the light emitting structure grown thereon.

The first electrode 121a may be formed on the first conductivity-type semiconductor layer 121, exposed as portions of the second conductivity-type semiconductor layer 121 are etched, and the second electrode 123a may be formed on the second conductivity-type semiconductor layer 123. In this case, in order to enhance an ohmic-contact function between the second conductivity-type semiconductor layer 123 and the second electrode 123a, a transparent electrode made of ITO, ZnO, or the like, may be further provided. In the case of the structure illustrated in FIG. 3, the first and second electrodes 121a and 123a are formed in the same direction, but the positions and connection structures of the first and second electrodes 121a and 123a may be variably modified as necessary.

In the case of the semiconductor light emitting device 200 according to the present example, an upper surface of the light emitting structure 120, namely, the surface of the second conductivity-type semiconductor layer 123, and a lateral surface of the light emitting structure 120 may be main light emission surfaces. Thus, by guiding light emitted toward the substrate 110 from the active layer 122 of the light emitting structure 120 upwardly, light extraction efficiency of the light emitting device can be enhanced. In the present example, the reflective structure 130 is formed on the surface of the substrate for growth of a semiconductor 110 opposed to the surface of the substrate for growth of a semiconductor 110 on which the light emitting structure 120 is formed, whereby light emitted toward the substrate 110 may be guided upwardly.

Here, a nano-rod layer 131 of the reflective structure 130 may be formed to be in contact with the substrate for growth of a semiconductor 110, and a plurality of nano-rods constituting the nano-rod layer 131 may be directly grown from the substrate for growth of a semiconductor 110.

In the present example, the plurality of nano-rods do not serve as a current path for applying an electrical signal to the first conductivity-type semiconductor layer 121, so the nano-rods may not necessarily be made of a material having electrical conductivity. However, in order to effectively dissipate heat generated from the light emitting structure 120 to the outside, the nano-rods may be made of a material having excellent thermal conductivity.

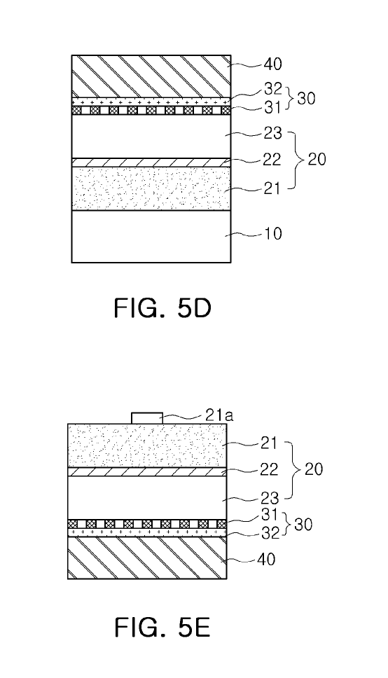

FIG. 4 is a perspective view schematically showing a semiconductor light emitting device according to a third example of the present disclosure.

With reference to FIG. 4, a semiconductor light emitting device 300 according to the present example may include a substrate for growth of a semiconductor 210, a light emitting structure 220 formed on the substrate for growth of a semiconductor 210, and a reflective structure 230 formed on the light emitting structure 220.

The light emitting structure 220 may include a first conductivity-type semiconductor layer 221, an active layer 222, and a second conductivity-type semiconductor layer 223 sequentially formed on the substrate for growth of a semiconductor 210, and include first and second electrodes 221a and 223a electrically connected to the first and second conductivity-type semiconductor layers 221 and 223, respectively.

In the present example, a main light emission surface of the light emitting structure 220 may include a lateral surface of the light emitting structure 220 and a surface of the light emitting structure 220 on which the substrate for growth of a semiconductor 210 are formed. Namely, light emitted from the active layer 222 of the light emitting structure 220 may be guided toward the substrate for growth of a semiconductor 210, and thus, a nano-rod layer 231 may be formed to be in contact with the second conductivity-type semiconductor layer 223.

In the present example, a plurality of nano-rods constituting the nano-rod layer 231 serves as a current path for applying an electrical signal to the second conductivity-type semiconductor layer 223 through the second electrode 223a, so the nano-rod layer 231 may be made of a material having electrical conductivity.

FIGS. 5A through 5E are schematic sectional views showing a method for fabricating the semiconductor light emitting device according to the first example of the present disclosure. Specifically, FIGS. 5A through 5E show a method for fabricating the semiconductor light emitting device illustrated in FIG. 1.

First, with reference to FIG. 5A, the light emitting structure 20 may be formed by sequentially forming the first conductivity-type semiconductor layer 21, the active layer 22, and the second conductivity-type semiconductor layer 23 on the substrate for growth of a semiconductor 10. As the substrate for growth of a semiconductor 10, a substrate made of a material such as sapphire, SiC, MgAl₂O₄, MgO, LiAlO₂, LiGaO₂, GaN, or the like, may be used.

In order to alleviate a lattice defect in the nitride semiconductor layer formed thereon, a buffer layer (not shown) may be formed on the substrate for growth of a semiconductor 10. The buffer layer may be employed as an undoped semiconductor layer made of a nitride, or the like, and is able to alleviate a lattice defect in the light emitting structure grown thereon.

The first and second conductivity-type semiconductor layers 21 and 23 and the active layer 22 may be formed by using a semiconductor layer growth process such as MOCVD, MBE, or HVPE known in the art.

Next, as shown in FIG. 5B, the nano-rod layer 31 including a plurality of nano-rods may be formed on an upper surface of the light emitting structure 20. The nano-rod layer 31 may be formed by bringing vapor of an organic metal precursor to the substrate according to a known deposition method, e.g., MOCVD, or irradiating beams to the substrate according to MBE to allow a target material to be grown from the substrate or the semiconductor layer. When the plurality of nano-rods are formed according to MOCVD, the nano-rods may be formed to have a desired shape by adjusting conditions such as an inflow amount, a deposition temperature, a time, and the like, of introduced reaction gases.

Here, the nano-rod layer 31 has a thickness which is an integer multiple of λ/(4n) (n: a refractive index of the nano-rods and λ is a wavelength of light emitted from the active layer), forming an ODR structure with the reflective metal layer 32 formed thereon.

And then, as shown in FIG. 5C, the reflective metal layer 32 is formed on the nano-rod layer 31 by using a known deposition process.

The reflective metal layer may include a material such as Ag, Ni, Al, Rh, Pd, Ir, Ru, Mg, Zn, Pt, Au, or the like, and in FIG. 5C, the reflective metal layer 32 is illustrated to be formed as a single layer, but alternatively, it may also have a structure including two or more layers.

For example, when the reflective metal layer 32 is formed by using e-beam or sputtering, the metal thin film may be formed in a state in which space between the plurality of nano-rods are not filled with a metal material due to step coverage characteristics. Namely, the space between the plurality of nano-rods may contain air. Here, in FIG. 5C, the reflective metal layer 32 is illustrated to be formed on the nano-rod layer 31, but the metal material for forming the reflective metal layer 32 may be deposited on portions between the plurality of nano-rods.

Thereafter, as shown in FIG. 5D, the conductive substrate 40 may be formed on the reflective structure 30 on a side opposite to the light emitting structure 20.

The conductive substrate 40 may serve as a support supporting the light emitting structure 20 when a lift-off process, or the like, is performed to remove the substrate for growth of a semiconductor 10, and may be formed as any one of a semiconductor substrate such as Si, GaAs, InP, InAs, and the like, a conductive oxide layer such as ITO (Indium Tin Oxide), ZrBₓ(for example, ZrB₂), ZnO, or the like, and a metal substrate such as CuW, Mo, Au. Al, or the like.

In the present example, the conductive substrate 40 may be bonded to the light emitting structure 20, via the reflective structure 30, by the medium of a conductive bonding layer, and in this case, the conductive bonding layer may be made of a eutectic metal material such as AuSn. Also, the conductive substrate 40 may be formed through electroplating, electroless plating, thermal evaporation, e-beam evaporation, sputtering, chemical vapor deposition (CVD), and the like.

Then, as shown in FIG. 5E, the substrate for growth of a semiconductor 10 may be removed through a laser lift-off process, or the like, by using the conductive substrate 40 as a support, and the first electrode 21a may be formed on the first conductivity-type semiconductor layer 21 exposed as the substrate for growth of a semiconductor 10 has been removed. The first electrode 21a may be formed on any portion of the upper surface of the first conductivity-type semiconductor layer 21, and here, in order to evenly distribute a current transferred to the first conductivity-type semiconductor layer 21, the first electrode 21a may be formed at a central portion.

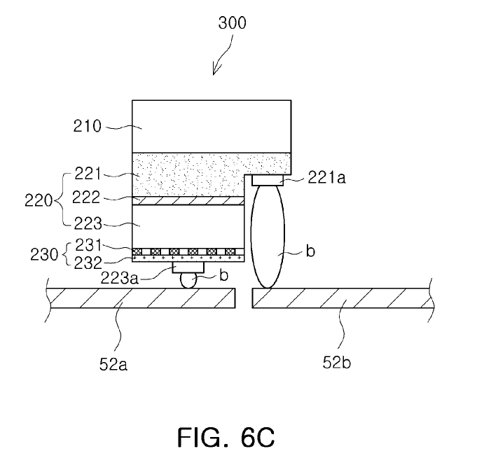

FIGS. 6A through 6C are schematic sectional views showing a mounting configuration of a semiconductor light emitting device package according to the first to third examples of the present disclosure.

Specifically, FIG. 6A is a view showing an example of a mounting configuration of the semiconductor light emitting device 100 illustrated in FIG. 1, FIG. 6B is a view showing an example of a mounting configuration of the semiconductor light emitting device 200 illustrated in FIG. 3, and FIG. 6C is a view showing an example of a mounting configuration of the semiconductor light emitting device 300 illustrated in FIG. 4.

First, with reference to FIG. 6A, a light emitting device package according to the present example includes first and second terminal units 50a and 50b, and the semiconductor light emitting device 100 may be electrically connected to the first and second terminal units 50a and 50b. In this case, the first conductivity-type semiconductor layer 21 may be wire-bonded to the second terminal unit 50b by means of the first electrode 21a formed thereon, and the second conductivity-type semiconductor layer 23 may be directly connected to the first terminal unit 50a through the conductive substrate 40.

A lens unit 60 may be formed above the semiconductor light emitting device 100 to encapsulate the semiconductor light emitting device 100 and fix the semiconductor light emitting device 100 and the first and second terminal units 50a and 50b. The lens unit 60, having a hemispherical shape, may serve to reduce Fresnel reflection at an interface to increase light extraction, as well as protecting the semiconductor light emitting device 100 and the wire. Here, the lens unit 60 may be made of a resin which may include any one of epoxy, silicon, strained silicon, a urethane resin, an oxetane resin, acryl, polycarbonate, and polyimide. Also, depressions and protrusions may be formed on an upper surface of the lens unit 60 to enhance light extraction efficiency and adjust a direction of emitted light. The shape of the lens unit 60 may be variably modified as necessary.

Although not shown, the lens unit 60 may include wavelength conversion phosphor particles for converting a wavelength of light emitted from the active layer of the semiconductor light emitting device 100. The phosphor may be any one of yellow phosphor, red phosphor, and green phosphor which converts a wavelength, or a plurality types of phosphors may be mixed to convert a plurality of wavelengths. The type of phosphors may be determined according to a wavelength emitted from the active layer of the semiconductor light emitting device 100. For instance, the lens unit 60 may include at least one or more of phosphor materials among a YAG-based phosphor material, a TAG-based phosphor material, a silicate-based phosphor material, a sulfide-based phosphor material, and a nitride-based phosphor material. For example, when a phosphor for performing wavelength conversion to yellow light is applied to a blue LED chip, a white semiconductor light emitting device may be obtained.

With reference to the example shown in FIG. 6B, a light emitting device package may include first and second terminal units 51a and 51b. The semiconductor light emitting device 200 may be electrically connected to the first and second terminal units 51a and 51b. In this case, first and second electrodes 121a and 123a formed on the first and second conductivity-type semiconductor layers 121 and 123 may be connected to the second and first terminal units 51b and 51a by conductive wires, respectively.

FIG. 6C shows a mounting configuration of the semiconductor light emitting device 300. First and second electrodes 221a and 223a formed on the first and second conductivity-type semiconductor layers 221 and 223 may be directly connected to first and second terminal units 52b and 52a so as to be flip-chip bonded, respectively.

However, the light emitting device packages illustrated in FIGS. 6A through 6C simply show how light emitting devices are mounted according to the first to third examples of the present disclosure, and specific mounting configurations and methods may be variably modified.

As set forth above, according to examples of the disclosure, a semiconductor light emitting device having enhanced light extraction efficiency through total reflection using a difference in refractive indices and the omni-directional reflector (ODR) structure can be provided.

In addition, a semiconductor light emitting device having improved reliability by preventing a degradation of a reflective metal layer due to high heat emitted from the light emitting structure, and a fabrication method thereof can be provided.

While the present disclosure has been shown and described in connection with the examples, it will be apparent to those skilled in the art that modifications and variations can be made without departing from the spirit and scope of the disclosure as defined by the appended claims.

What is claimed is:

1. A semiconductor light emitting device comprising:
a light emitting structure including:
a first conductivity-type semiconductor layer, an active layer, and a second conductivity-type semiconductor layer; and
a reflective structure formed on the light emitting structure, the reflective structure including:
a nano-rod layer comprised of a plurality of nano-rods and air filling space arranged between the plurality of nano-rods, and
a reflective metal layer formed on the nano-rod layer.

2. The semiconductor light emitting device of claim 1, wherein the space in which the plurality of nano-rods are formed have different refractive indices than the space filled with air arranged between the nano-rods, with respect to a wavelength of light emitted from the active layer.

3. The semiconductor light emitting device of claim 1, wherein the reflective structure is formed such that the nano-rod layer thereof is in direct contact with the second conductivity-type semiconductor layer of the light emitting structure.

4. The semiconductor light emitting device of claim 1, wherein the plurality of nano-rods are comprised of a material having electrical conductivity and light transmissivity.

5. The semiconductor light emitting device of claim 4, wherein the material having electrical conductivity and light transmissivity includes one of a transparent conductive oxide and a transparent conductive nitride.

6. The semiconductor light emitting device of claim 5, wherein the transparent conductive oxide is at least one of ITO, CIO, and ZnO.

7. The semiconductor light emitting device of claim 1, wherein the thickness of the nano-rod layer is defined by an integer multiple of λ/(4n), wherein n is a refractive index of the nano-rods and λ is a wavelength of light emitted from the active layer.

8. The semiconductor light emitting device of claim 1, further comprising a conductive substrate formed on the reflective structure.

9. The semiconductor light emitting device of claim 1, further comprising a substrate for growth of a semiconductor having one surface on which the light emitting structure is formed.

10. The semiconductor light emitting device of claim 9, wherein the reflective structure is formed on a surface of the substrate for growth of the semiconductor opposite the surface on which the light emitting structure is formed.

11. The semiconductor light emitting device of claim 9, wherein the reflective structure is formed on the second conductivity-type semiconductor layer of the light emitting structure formed on the substrate for growth of the semiconductor.

12. A light emitting device package comprising:
a semiconductor light emitting device including:
a light emitting structure including a first conductivity-type semiconductor layer,
an active layer,
a second conductivity-type semiconductor layer, and
a reflective structure formed on the light emitting structure and including a nano-rod layer comprised of a plurality of nano-rods and air filling space between the plurality of nano-rods and a reflective metal layer formed on the nano-rod layer;
a first electrode;
a first terminal unit; and
a second terminal unit,
wherein the semiconductor light emitting device is electrically connected to the first and second terminal units.

13. The light emitting device package of claim 12, further comprising:
lens unit formed above the semiconductor light emitting device.

14. The light emitting device package of claim 13, wherein the lens unit encapsulates the semiconductor light emitting device.

15. The light emitting device package of claim 13, wherein the lens unit fixes the semiconductor light emitting device 100 and the first and second terminal units.

16. The light emitting device package of claim 13, wherein the lens unit is made of a resin.

17. The light emitting device package of claim 16, wherein the resin comprises any one of epoxy resin, silicon resin, strained silicon resin, a urethane resin, an oxetane resin, acryl resin, polycarbonate resin, and polyimide resin.

18. The light emitting device package of claim 13, wherein depressions and protrusions are formed on an upper surface of the lens unit.

19. The light emitting device package of claim 13, wherein the lens unit includes wavelength conversion phosphor particles for converting a wavelength of light emitted from the active layer of the semiconductor light emitting device.

20. The light emitting device package of claim 13, wherein the lens unit has a hemispherical shape.
